(19) United States
(12) Patent Application Publication
(10) Pub. No.: US 2025/0309031 A1
(43) Pub. Date: Oct. 2, 2025

(54) SEMICONDUCTOR DEVICE AND METHOD FOR FORMING THE SAME

(71) Applicant: JCET STATS ChipPAC Korea Limited, Incheon (KR)

(72) Inventors: SeungHyun LEE, Incheon (KR); YeoJun YUN, Incheon (KR); HeeSoo LEE, Incheon (KR)

(21) Appl. No.: 19/080,923

(22) Filed: Mar. 16, 2025

(30) Foreign Application Priority Data
Mar. 26, 2024 (CN) 202410352410.6

(51) Int. Cl. H01L 23/367; H01L 21/48; H01L 21/56; H01L 23/00; H01L 23/498; H01L 23/538; H01L 23/552; H01L 25/16

(52) U.S. Cl. CPC H01L 23/3675; H01L 21/4853; H01L 21/4882; H01L 21/565; H01L 23/49833; H01L 23/538; H01L 23/552; H01L 24/32; H01L 25/16; H01L 24/16; H01L 2224/16225; H01L 2224/32245; H01L 2924/19105

(57) ABSTRACT

A semiconductor device and a method for forming the same are provided. The method includes: providing a package substrate; mounting at least one preformed conductive block and at least one electronic component on a top surface of the package substrate, wherein the preformed conductive block includes an insulating substrate and at least one conductive pillar extending through the insulating substrate; forming an encapsulant on the top surface of the package substrate, wherein the encapsulant exposes a top surface of the conductive pillar of the conductive block and a top surface of the electronic component; and forming a heat dissipation cap on the encapsulant to electrically couple the heat dissipation cap to the conductive pillar of the conductive block and to thermally couple the heat dissipation cap to the electronic component.

### TECHNICAL FIELD

The present application generally relates to semiconductor technology, and more particularly, to a semiconductor device and a method for forming the same.

### BACKGROUND OF THE INVENTION

The semiconductor industry is constantly faced with complex integration challenges as consumers want their electronics to be smaller, faster and higher performance with more and more functionalities packed into a single device. In order to meet the needs of consumers, more and more electronic components are tightly integrated within a single device or package. Yet, due to the tight integration, electromagnetic interference (EMI) may easily occur among the electronic components, and heat generated by one electronic component may be blocked by another electronic components from dissipation. Typically, an EMI shield may be formed over the device to cover the electronic component that is susceptible to or generates EMI, and a heat spreader may be attached on the device to dissipate the heat generated by the electronic components. However, the conventional method for forming the EMI shield and the heat spreader is complex, resulting in excess cost and low reliability.

Therefore, a need exists for a semiconductor device with reduced cost.

### SUMMARY OF THE INVENTION

An objective of the present application is to provide a semiconductor device with low cost.

According to an aspect of the present application, a method for forming a semiconductor device is provided. The method may include: providing a package substrate; mounting at least one preformed conductive block and at least one electronic component on a top surface of the package substrate, wherein the preformed conductive block includes an insulating substrate and at least one conductive pillar extending through the insulating substrate; forming an encapsulant on the top surface of the package substrate, wherein the encapsulant exposes a top surface of the conductive pillar of the conductive block and a top surface of the electronic component; and forming a heat dissipation cap on the encapsulant to electrically couple the heat dissipation cap to the conductive pillar of the conductive block and to thermally couple the heat dissipation cap to the electronic component.

According to another aspect of the present application, a method for forming a semiconductor device is provided. The method may include: providing a package substrate; mounting at least one preformed conductive block and at least one electronic component on a top surface of the package substrate; forming an encapsulant on the top surface of the package substrate, wherein the encapsulant exposes a top surface of the conductive block; and forming a heat dissipation cap on the encapsulant to connect with the conductive block, such that the conductive block and the heat dissipation cap form an enclosed structure to accommodate the electronic component.

According to still another aspect of the present application, a semiconductor device is provided. The semiconductor device may include: a package substrate; at least one preformed conductive block and at least one electronic component mounted on a top surface of the package substrate, wherein the preformed conductive block includes an insulating substrate and at least one conductive pillar extending through the insulating substrate; an encapsulant formed on the top surface of the package substrate, wherein the encapsulant exposes a top surface of the conductive pillar of the conductive block and a top surface of the electronic component; and a heat dissipation cap formed on the encapsulant, wherein the heat dissipation cap is electrically coupled to the conductive pillar of the conductive block and is thermally coupled to the electronic component.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 is a cross-sectional view illustrating a semiconductor device according to an embodiment of the present application.

FIG. 2 is a cross-sectional view illustrating a semiconductor device according to another embodiment of the present application.

FIG. 3 is a cross-sectional view illustrating a semiconductor device according to another embodiment of the present application.

FIG. 4 is a cross-sectional view illustrating a semiconductor device according to another embodiment of the present application.

FIG. 5 is a cross-sectional view illustrating a semiconductor device according to another embodiment of the present application.

FIGS. 6A to 6H are cross-sectional views illustrating various steps of a method for forming a semiconductor device according to an embodiment of the present application.

FIGS. 7A to 7H are cross-sectional views illustrating various steps of a method for forming a semiconductor device according to another embodiment of the present application.

FIGS. 8A to 8D are cross-sectional views illustrating various steps of a method for forming a semiconductor device according to another embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

FIG. 1 illustrates a cross-sectional view of a semiconductor device 100 according to an embodiment of the present application. The semiconductor device 100 may include a package substrate 110, a plurality of electronic components 121, 122, 123 and 124 and at least one preformed conductive block 130 mounted on a top surface of the package substrate 110. An encapsulant 140 may be formed on the top surface of the package substrate 110 to encapsulate the various components thereon, and a heat dissipation cap 150 may be further formed on the encapsulant 140.

The package substrate 110 can provide support and connectivity for electronic components and devices mounted thereon. By way of example, the package substrate 110 may include a printed circuit board (PCB), a carrier substrate, a semiconductor substrate with electrical interconnections, a ceramic substrate, a laminate interposer, a strip interposer, a leadframe, or other suitable substrates. The package substrate 110 may include any structure on or in which an integrated circuit system can be fabricated. In some examples, the package substrate 110 may include redistribution structures having one or more dielectric layers and one or more conductive layers between and through dielectric layers. The conductive layers may define pads, traces and plugs through which electrical signals or voltages can be distributed horizontally and vertically across the redistribution structures.

The electronic components 121 to 124 may include any of a variety of types of semiconductor dice, semiconductor packages, or discrete devices. For example, the electronic components 121 to 124 may include a digital signal processor (DSP), a microcontroller, a microprocessor, a network processor, a power management processor, an audio processor, a video processor, a radiofrequency (RF) circuit, a wireless baseband system-onchip (SoC) processor, a sensor, a memory controller, a memory device, an application specific integrated circuit, etc. In some other examples, the electronic components 121 to 124 may be passive components such as resistors, capacitors, inductors, switches, or any other suitable electronic devices. By way of example, the electronic components 121 and 122 are discrete devices, and the electronic components 123 and 124 are semiconductor dice.

The conductive block 130 is preformed and includes an insulating substrate 134 and a conductive pillar 132 extending through the insulating substrate 134. The conductive block 130 may surround the electronic components 121 to 124. In some examples, the conductive block 130 may be formed as a single piece and may have a square, rectangular or circular shape to surround the electronic components 121 to 124. In some examples, a plurality of conductive blocks 130 may be positioned on the package substrate 110 to form an enclosure to surround the electronic components 121 to 124. In some examples, the conductive blocks 130 may be distributed at four sides of the electronic components 121 to 124. In that case, the conductive blocks 130 may not fully enclose the electronic components 121 to 124 at their lateral sides, with the encapsulant material of the encapsulant 140 filled in gaps between the adjacent conductive blocks 130.

In some embodiments, the preformed conductive block 130 may include an e-bar block. The e-bar block may include at least one conductive pillar (for example, a copper pillar) which is surrounded by a dielectric layer such as an insulative polymeric material or composite. To be more specific, a bottom surface of the conductive pillar may be exposed from or protrude from a bottom surface of the dielectric layer to be electrically connected with a contact pad of the substrate 110. Similarly, a top surface of the conductive pillar may be exposed from or protrude from a top surface of the dielectric layer for electrical contact purpose, for example, in connection with the heat dissipation cap 150. The number of conductive pillars included in the conductive block 130 may vary according to actual needs of the semiconductor device 100.

In some embodiments, the preformed conductive block 130 may include a molded inter-connect substrate (MIS). Generally, the MIS is an effective semiconductor substrate technology for a thin semiconductor package by routing copper traces (or interconnects) pre-molded into the substrate. An example for preforming the MIS may include providing a carrier (for example, a cold rolled steel sheet (SPCC), followed by plating one or more metal (for example, copper) layers on the carrier. The one or more metal layers are configured for making horizontal or vertical interconnects. Then, the one or more metal layers may be encapsulated by performing an over-mold procedure if an epoxy molding compound (EMC) material is used, or by performing a lamination procedure if a film material such as Ajinomoto™ Build-up Film (ABF) is used. Further, a surface-grinding process may be performed to expose a portion of the metal layer, and an etching process may be performed to at least remove a portion of the carrier.

In some embodiments, such as the embodiment shown in FIG. 1, a plurality of solder bumps may be formed on contact pads on the top surface of the package substrate 110. The electronic components 121 to 124 and the conductive block 130 may be placed on the top surface of the package substrate 110 and in contact with the solder bumps, and then the solder bumps may be reflowed to mount the electronic components 121 to 124 and the conductive block 130 onto the top surface of the package substrate 110 via the solder bumps, thus forming electrical connection between the conductive layers in the package substrate 110 and the electronic components 121 to 124 and the conductive block 130. For example, the conductive pillar 132 of the conductive block 130 may be electrically connected to a reference node or potential, for example, a ground layer in the package substrate 110.

Referring to FIG. 1, the encapsulant 140 is formed on the top surface of the package substrate 110. The encapsulant 140 may be made of a polymer composite material, such as epoxy resin with filler, epoxy acrylate with filler, or polymer with proper filler, but the scope of this application is not limited thereto. In the example shown in FIG. 1, a top surface of the conductive block 123, or a top surface of the conductive pillar 132 protruding from the insulating substrate 134 is substantially flush with a top surface of the electronic component 123, but is higher than respective top surfaces of the electronic components 121, 122 and 124. Thus, the encapsulant 140 exposes the top surface of the conductive pillar 132 of the conductive block 130 and the top surface of the electronic component 123, but encapsulates and covers the electronic components 121, 122 and 124. Consequently, the heat dissipation cap 150 formed on the encapsulant 140 can be electrically coupled to the conductive pillar 132 of the conductive block 130 and thermally coupled to the top surface of the electronic component 123.

In the example shown in FIG. 1, the heat dissipation cap 150 may include an electromagnetic interference (EMI) shield 152 formed on the encapsulant 140 and electrically coupled to the conductive pillar 132 of the conductive block 130, a thermal interface material (TIM) layer 156 formed on the EMI shield 152, and a heat spreader 154 attached on TIM layer 156 and thermally coupled to the top surface of the electronic component 123 via the TIM layer 156 and the EMI shield 152.

The EMI shield 152 may include copper, aluminum, iron, or any other suitable material for EMI shielding. In some embodiments, the EMI shield 152 may be formed by spray coating, plating, sputtering, or any other suitable metal deposition process. The EMI shield 152 may be formed on the top surface of the encapsulant 140, and cover the top surface of the electronic component 123 and the top surface of the conductive pillar 132 of the conductive block 130 to enclose the electronic components 121 to 124 of the semiconductor device 100. The EMI shield 152 may form a closed-loop circuit with the conductive pillar 132 of the conductive block 130 and the ground layer in the package substrate 110, so as to direct an induced EMI current to the ground layer in the package substrate 110.

The TIM layer 156 may include solder, indium, silver, an indium/silver alloy, or other suitable materials. In some embodiments, the TIM layer 156 may be formed by spray coating, plating, sputtering, or any other suitable metal deposition process. The TIM layer 156 can be used to solder the EMI shield 152 together with the heat spreader 154, to enhance the adhesion between the EMI shield 152 and the heat spreader 154.

The heat spreader 154 may include a metal lid made of copper, aluminum, nickel-plated copper, nickel-plated aluminum, or other materials with a high thermal conductivity. The heat spreader 154 may be attached on the TIM layer 156 and thermally coupled to the electronic component 123 through the TIM layer 156 and the EMI shield 152, so as to dissipate heat generated by the electronic component 123 and other electronic components to the external environment.

Continuing referring to FIG. 1, the semiconductor device 100 may further include a plurality of conductive bumps 160 formed on a bottom surface of the package substrate 110. In the example shown in FIG. 1, the conductive bumps 160 are illustrated as solder bumps, but the present application is not limited thereto. In some other embodiments, the conductive bumps 160 may include conductive pillars, copper balls, etc. In a case where the semiconductor device 100 is mounted on an external device or substrate such as a printed circuit board (PCB), the conductive bumps 160 may be used for electrically connecting the semiconductor device 100 to the external device or substrate.

In the semiconductor device 100 shown in FIG. 1, the preformed conductive block 130 (for example, the e-bar block, or the molded inter-connect substrate) is connected to the heat dissipation cap 150 to form an enclosed structure, and the electronic components 121 to 124 are accommodated within the enclosed structure. The enclosed structure can not only work as an EMI shielding structure for the electronic components 121 to 124, but also dissipate heat generated by the electronic components 121 to 124. The preformed conductive block 130 is generally lower in cost of manufacture than conventional metal bars and can be easily attached on the package substrate 110 by a surface mount-technology (SMT). Thus, the cost for forming the semiconductor device 100 can be reduced compared with conventional processes. In addition, the preformed conductive block 130 may serve as a leg to support the heat dissipation cap 150 on the package substrate 110, thereby eliminating the need for additional supporting structures and enhancing the rigidity of the semiconductor device 100.

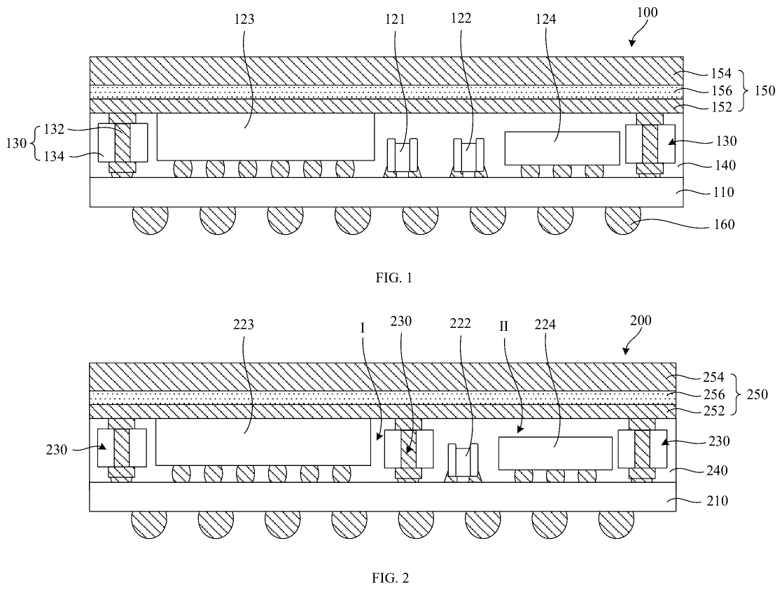

Moreover, the preformed conductive block 130 can not only be used to form the full shielding structure of the semiconductor device 100 shown in FIG. 1, but also be used to form a compartment shielding structure of a semiconductor device 200 shown in FIG. 2.

Referring to FIG. 2, a cross-sectional view of the semiconductor device 200 having a compartment shielding structure is illustrated according to an embodiment of the present application. The semiconductor device 200 may have some similar structures and configurations as the semiconductor device 100 shown in FIG. 1. The similar or same parts between the semiconductor device 200 and the semiconductor device 100 will not be repeated herein.

Specifically, as shown in FIG. 2, the semiconductor device 200 may include a package substrate 210, a plurality of electronic components 222, 223 and 224 and at least one preformed conductive block 230 mounted on a top surface of the package substrate 210, an encapsulant 240 formed on the top surface of the package substrate 210, and a heat dissipation cap 250 formed on the encapsulant 240. The heat dissipation cap 250 has a multi-layer laminated structure which includes an EMI shield 252, a TIM layer 256 and a heat spreader 254. Different from the semiconductor device 100 shown in FIG. 1, the preformed conductive block 230 of the semiconductor device 200 forms two different compartments, i.e., a first compartment I for accommodating the electronic component 223, and a second compartment II for accommodating the electronic components 222 and 224. It is beneficial when electromagnetic interferences exist between the electronic component 223 and the electronic components 222 and 224. In some preferred embodiments, the preformed conductive block 230 may extend substantially across the package substrate 210 to provide better EMI shielding performance. Furthermore, the preformed conductive block 230 also provides a heat dissipation path from the internal of the semiconductor device 200 to the heat dissipation cap 250, which improves the heat dissipation performance of the entire semiconductor device 200.

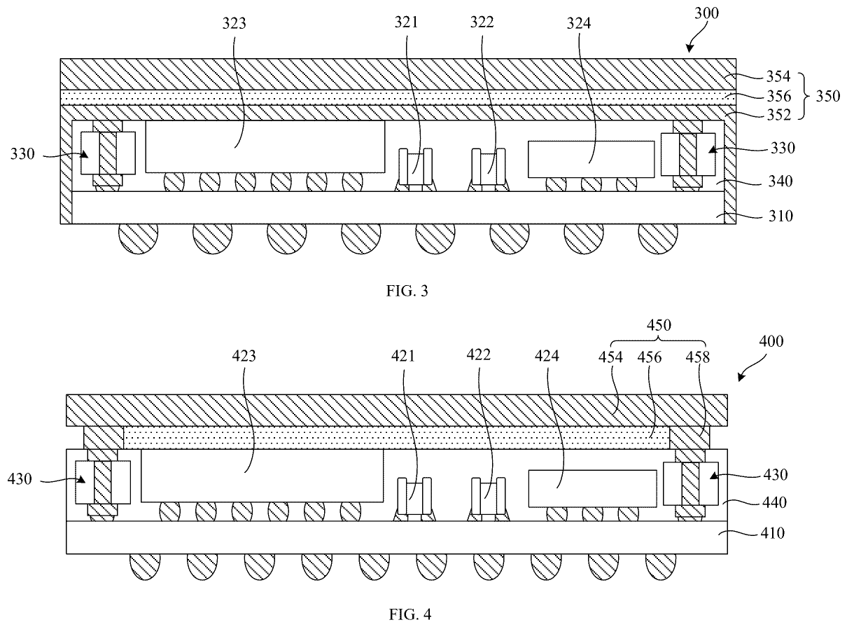

FIG. 3 illustrates a cross-sectional view of a semiconductor device 300 according to another embodiment of the present application. The semiconductor device 300 may have some similar structures and configurations as the semiconductor device 100 shown in FIG. 1. The similar or same parts between the semiconductor device 300 and the semiconductor device 100 will not be repeated herein.

Specifically, as shown in FIG. 3, the semiconductor device 300 may include a package substrate 310, a plurality of electronic components 321, 322, 323 and 324 and at least one preformed conductive block 330 mounted on a top surface of the package substrate 310, an encapsulant 340 formed on the top surface of the package substrate 310, and a heat dissipation cap 350 formed on the encapsulant 340. The heat dissipation cap 350 has a multi-layer laminated structure which includes an EMI shield 352, a TIM layer 356 and a heat spreader 354. Different from the semiconductor device 100 shown in FIG. 1, the EMI shield 352 of the semiconductor device 300 may be a conformal shield that follows the shapes and/or contours of the encapsulant 340 and the substrate 310. In particular, the EMI shield 352 covers a top surface of the electronic component 323, a top surface of the conductive pillar of the conductive block 330, top and lateral surfaces of the encapsulant 340, and lateral surfaces of the package substrate 310. The conformal EMI shield 352 can provide better EMI shielding performance as well as better heat dissipation performance of the entire semiconductor device 300.

FIG. 4 illustrates a cross-sectional view of a semiconductor device 400 according to another embodiment of the present application. The semiconductor device 400 may have some similar structures and configurations as the semiconductor device 100 shown in FIG. 1. The similar or same parts between the semiconductor device 400 and the semiconductor device 100 will not be repeated herein.

Specifically, as shown in FIG. 4, the semiconductor device 400 may include a package substrate 410, a plurality of electronic components 421, 422, 423 and 424 and at least one preformed conductive block 430 mounted on a top surface of the package substrate 410, an encapsulant 440 formed on the top surface of the package substrate 410, and a heat dissipation cap 450 formed on the encapsulant 440. Different from the semiconductor device 100 shown in FIG. 1, the heat dissipation cap 450 of the semiconductor device 400 may include an interconnection layer 458 formed on a top surface of the conductive pillar of the conductive block 430, a TIM layer 456 formed on the top surface of the electronic component 423, and a heat spreader 454 attached on the interconnection layer 458 and the TIM layer 456. The interconnection layer 458 may be made of a conductive material such as solder, conductive ink, conductive epoxy, etc. Thus, the heat spreader 454 can be electrically coupled to the conductive pillar of the conductive block 430 through the interconnection layer 458 and thermally coupled to the electronic component 423 through the TIM layer 456.

In some examples, the TIM layer 456 may include a material having a melting point near room temperature, such as Ga, InGa, InGaSn, etc. That is, the TIM layer 456 may be liquid at room temperature. The interconnection layer 458 together with the heat spreader 454 can enclose the liquid TIM layer 456, and prevent it from leaking to the outside. The liquid TIM layer 456 can offer several advantages owing to their intrinsic high thermal conductivities, flexibility, and low melting points. For example, the liquid TIM layer 456 can cover rough surfaces adequately and fill air voids, further reducing the interface resistance. However, the present application is not limited thereto. In some other examples, the TIM layer 456 may include solder, silver, an indium/silver alloy, or other suitable materials.

In the semiconductor device 400 shown in FIG. 4, the heat spreader 454 together with the interconnection layer 458 and the conductive block 430 serves as an EMI shield. In some embodiments, the interconnection layer 458 may surround the TIM layer 456, with no other TIM material filled between the heat spreader 454 and the encapsulant layer 440, but in some alternative embodiments, an additional TIM material may be formed outside of the interconnection layer 458 to further improve heat transfer between the heat spreader 454 and the encapsulant layer 440.

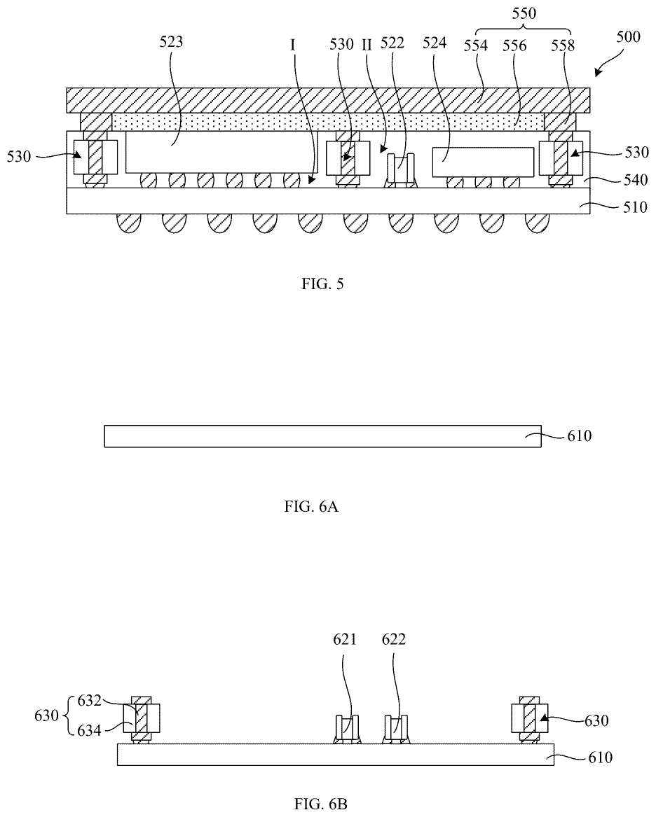

FIG. 5 illustrates a cross-sectional view of a semiconductor device 500 according to another embodiment of the present application. The semiconductor device 500 may have some similar structures and configurations as the semiconductor device 400 shown in FIG. 4. The similar or same parts between the semiconductor device 500 and the semiconductor device 400 will not be repeated herein.

Specifically, as shown in FIG. 5, the semiconductor device 500 may include a package substrate 510, a plurality of electronic components 522, 523 and 524 and at least one preformed conductive block 530 mounted on a top surface of the package substrate 510, an encapsulant 540 formed on the top surface of the package substrate 510, and a heat dissipation cap 550 formed on the encapsulant 540. The heat dissipation cap 550 may include an interconnection layer 558 formed on a top surface of the conductive pillar of the conductive block 530, a TIM layer 556 formed on the top surface of the electronic component 523, and a heat spreader 554 attached on the interconnection layer 558 and the TIM layer 556. In some examples, the TIM layer 556 may include a material having a melting point near room temperature, such as Ga, InGa, InGaSn, etc. The interconnection layer 558 may enclose the liquid TIM layer 556, and prevent it from leaking to the outside. In some examples, the TIM layer 556 may include solder, silver, an indium/silver alloy, or other suitable materials. Different from the semiconductor device 400 shown in FIG. 4, the preformed conductive block 530 of the semiconductor device 500 forms two different compartments, i.e., a first compartment I for accommodating the electronic component 523, and a second compartment II for accommodating the electronic components 522 and 524. It is beneficial when electromagnetic interferences exist between the electronic component 523 and the electronic components 522 and 524.

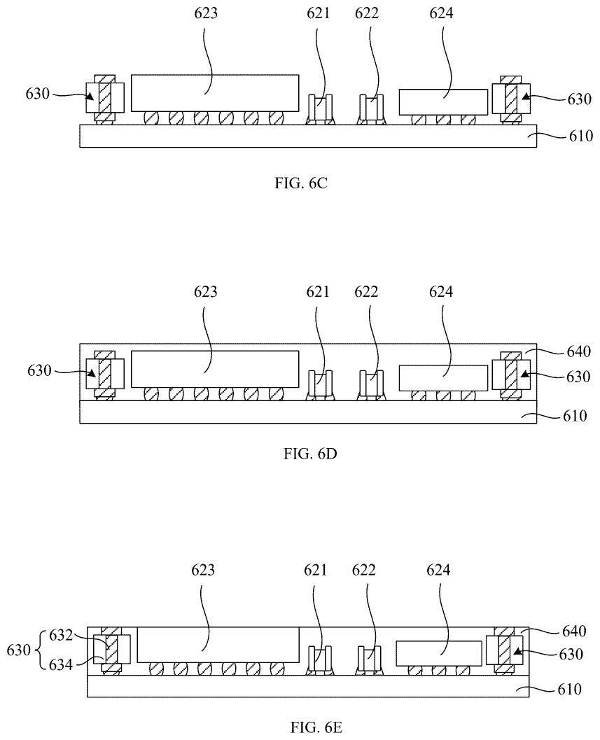

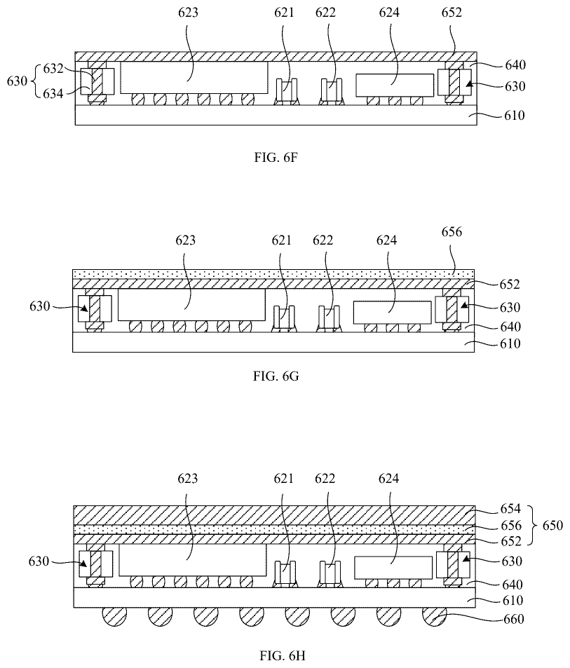

Referring to FIGS. 6A to 6H, various steps of a method for forming a semiconductor device are illustrated according to an embodiment of the present application. For example, the method may be used to form the semiconductor device 100 shown in FIG. 1. In the following, the method will be described with reference to FIGS. 6A to 6H in more details.

Referring to FIG. 6A, a package substrate 610 is provided. The package substrate 610 can provide support and connectivity for electronic components and devices mounted thereon. By way of example, the package substrate 610 may include a printed circuit board (PCB), a carrier substrate, a semiconductor substrate with electrical interconnections, a ceramic substrate, a laminate interposer, a strip interposer, a leadframe, or other suitable substrates. In some examples, the package substrate 610 may include redistribution structures having one or more dielectric layers and one or more conductive layers between and through dielectric layers. The conductive layers may define pads, traces and plugs through which electrical signals or voltages can be distributed horizontally and vertically across the redistribution structures. In some embodiments, the package substrate 610 may include a plurality of predefined substrate units arranged in a strip manner, and a singulation process may be performed in a subsequent step to singulate each individual package from the package strip along singulation channels.

Referring to FIG. 6B, electronic components 621 and 622 and at least one preformed conductive block 630 are mounted on a top surface of the package substrate 610.

By way of example, the electronic components 621 and 622 may include discrete devices or other small components. The preformed conductive block 630 may includes an insulating substrate 634 and a conductive pillar 632 extending through the insulating substrate 634. For example, the preformed conductive block 630 may include an e-bar block or a molded inter-connect substrate (MIS). The conductive block 630 may form an enclosure to surround the electronic components 621 and 622. In some embodiments, solder materials may be deposited onto the contact pads formed on the top surface of the package substrate 610, and the electronic components 621 and 622 and the preformed conductive block 630 are placed on the top surface of the package substrate 610 and in contact with the solder materials. Then, the solder materials may be reflowed to mount the electronic components 621 and 622 and the preformed conductive block 630 on the top surface of the package substrate 610 via the solder materials, thus forming electrical connection therebetween.

Referring to FIG. 6C, electronic components 623 and 624 are mounted on the top surface of the package substrate 610. The electronic components 623 and 624 may include semiconductor chips, semiconductor dice, or semiconductor packages. In the example shown in FIG. 6C, the electronic component 623 is higher than the electronic components 621, 622 and 624, and at a same level as the conductive block 630. Thus, a top surface of the conductive block 630 is substantially flush with a top surface of the electronic component 623, but higher than top surfaces of the electronic components 621, 622 and 624.

It could be understood that the operations illustrated in FIGS. 6B and 6C are only examples, and the present application is not limited thereto. In some other embodiments, the electronic components 621 and 622, the preformed conductive block 630 and the electronic components 623 and 624 may be mounted on the top surface of the package substrate 610 in different orders.

Referring to FIG. 6D, an encapsulant 640 is formed on the top surface of the package substrate 610 to encapsulate the conductive block 630 and the electronic components 621, 622, 623 and 624. In some embodiments, a molding material may be formed on the top surface of the package substrate 610 to form the encapsulant 640. The molding material may include epoxy resin, epoxy resin with filler, epoxy acrylate with filler, or polymer with proper filler, but the scope of this application is not limited thereto. In some embodiments, the encapsulant 640 may be formed by using compressive molding, transfer molding, liquid encapsulant molding, or other suitable molding processes.

Referring to FIG. 6E, the encapsulant 640 is grinded to expose the top surface of the conductive pillar 632 of the conductive block 630 and the top surface of the electronic component 623.

In some embodiments, a grinder may be used to remove an upper portion of the encapsulant 640. In some embodiments, as the grinding process can planarize a top surface of the entire package, an upper portion of the conductive block 630 or an upper portion of the conductive block 630 may be removed simultaneously to ensure the top surface of the conductive block 630 and the top surface of the electronic component 623 can be substantially flush or coplanar with each other.

It could be understood that the operations illustrated in FIGS. 6C and 6D are only examples, and the present application is not limited thereto. In some other embodiments, a film-assisted molding (FAM) process may be used to form the encapsulant. The FAM process enables easy release of the encapsulated package from a molding chase since the molding material contacts assisting films instead of the molding chase. Further, the FAM process can directly form the encapsulant exposing the top surface of the conductive pillar 632 of the conductive block 630 and the top surface of the electronic component 623, and there is no need to grind the encapsulant.

Referring to FIG. 6F, an electromagnetic interference (EMI) shield 652 is formed on the top surface of the encapsulant 640. The EMI shield 652 is electrically coupled to the conductive pillar 632 of the conductive block 630 and thermally coupled to the electronic component 623. In some embodiment, the EMI shield 652 may be formed from copper, aluminum, iron, or any other suitable material for EMI shielding. In some embodiments, the EMI shield 652 may be formed by sputtering, spray coating, plating, or any other suitable metal deposition process.

Referring to FIG. 6G, a thermal interface material (TIM) layer 656 is formed on the EMI shield 652. In some embodiments, the TIM layer 656 may include solder, indium, silver, an indium/silver alloy, or other suitable materials. In some embodiments, the TIM layer 656 may be formed by spray coating, plating, sputtering, or any other suitable metal deposition process.

In some embodiments, when the package substrate 610 includes a plurality of predefined substrate units arranged in a strip manner, a singulation process may be performed to singulate each individual package from the package strip along singulation channels after the TIM layer 656 is formed. For example, the package strip can be singulated into individual packages using a saw blade.

Referring to FIG. 6H, a heat spreader 654 is attached on the TIM layer 656. Thus, the heat spreader 654 is thermally coupled to the electronic component 623 through the TIM layer 656.

In some embodiments, the heat spreader 654 may include a metal lid made of copper, aluminum, nickel-plated copper, nickel-plated aluminum, or other materials with a high thermal conductivity. In some embodiments, the TIM layer 656 may be reflowed to solder the heat spreader 654 and the TIM layer 656 together, and solder the EMI shield 652 and the TIM layer 656 together. Specifically, the TIM layer 656 may be heated above its melting point, such that the TIM layer 656 and the heat spreader 654/the EMI shield 652 may react and form an intermetallic compound (IMC). The IMC can enhance the adhesion between the TIM layer 656 and the heat spreader 654/the EMI shield 652. Consequently, the heat spreader 654 can be attached on the TIM layer 656 and thermally coupled to the electronic component 623 through the TIM layer 656 and the EMI shield 652, so as to dissipate heat generated by the electronic component 623 and other electronic components. However, the present is not limited to the above examples. In some other embodiments, the heat spreader 654 may be formed on the TIM layer 656 by a deposition process, and a thickness of the heat spreader 654 can be accurately controlled by the deposition process.

In some embodiments, a solder material may be printed or deposited onto contact pads exposed from a bottom surface of the package substrate 610, and then the solder material may be reflowed by heating the material above its melting point to form conductive bumps 660. In some other embodiments, the conductive bumps 660 may be compression bonded or thermocompression bonded onto the contact pads exposed from the bottom surface of the package substrate 610. In the example shown in FIG. 6H, the conductive bumps 660 are illustrated as solder bumps, but the present application is not limited thereto. In some other embodiments, the conductive bumps 660 may include conductive pillars, copper balls, micro bumps, etc.

In some embodiments, the singulation process is performed not immediately after forming the TIM layer 656, but after attaching or depositing a heat spreader strip on the EMI shield 652. The heat spreader strip can be singulated together with the package substrate 610 to form individual semiconductor devices, thereby increasing the productivity.

In the above method described with reference to FIGS. 6A-6H, a heat dissipation cap 650 including the EMI shield 652, the TIM layer 656 and the heat spreader 654 is connected to the preformed conductive block 630 to form an enclosed structure, and the electronic components 621, 622, 623 and 624 are accommodated within enclosed structure. The enclosed structure not only can work as an EMI shielding structure for the electronic components 621, 622, 623 and 624, but also can dissipate heat generated by the electronic components 621, 622, 623 and 624. As the preformed conductive block 630 is generally cheaper than conventional metal bars and can be easily attached on the package substrate 610 by a surface mount-technology. Thus, the cost for forming the semiconductor device can be reduced.

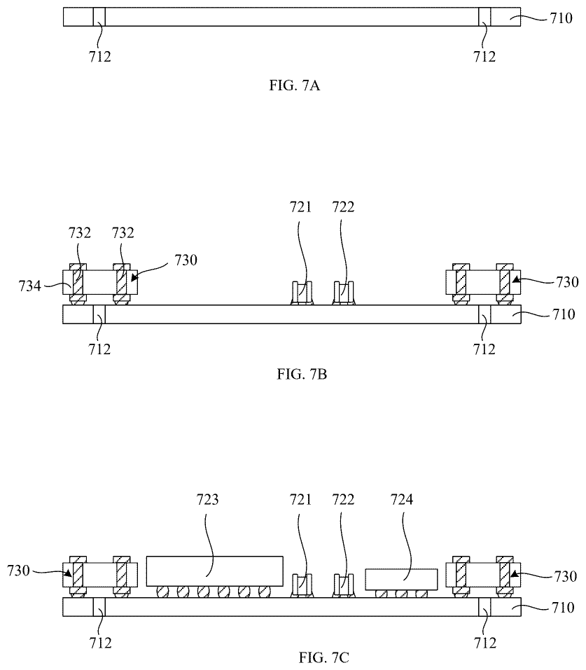

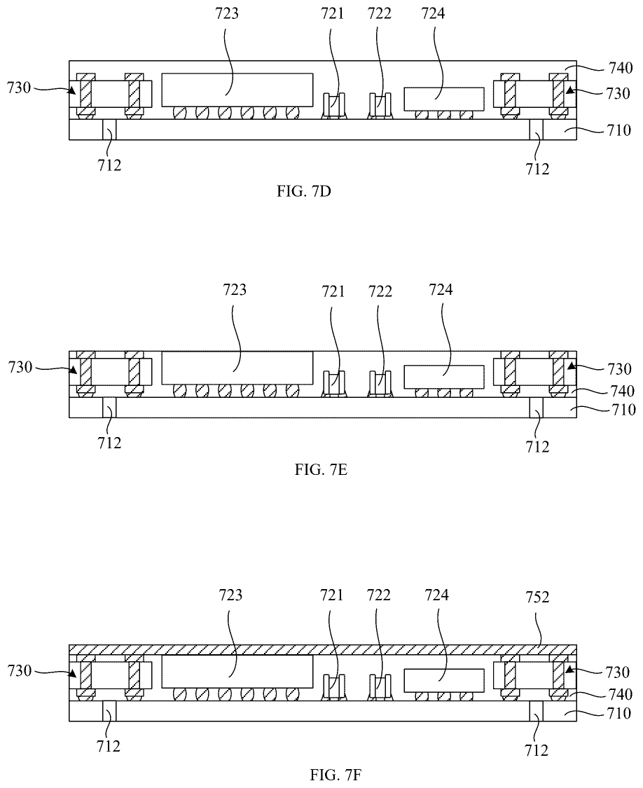

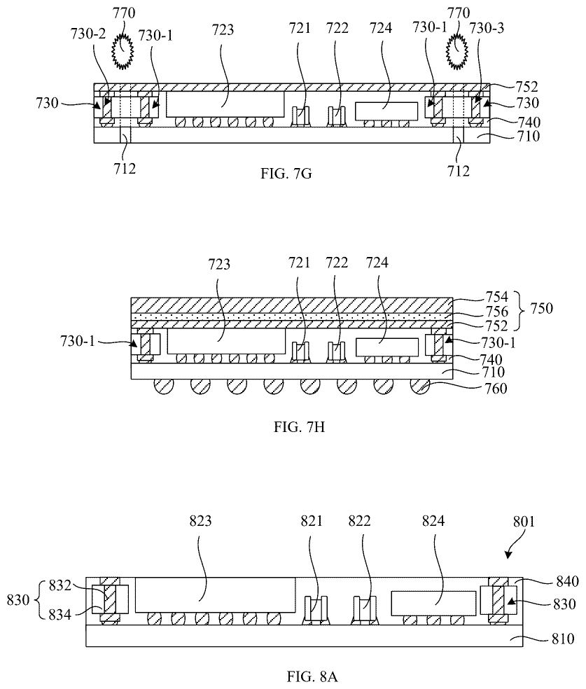

Referring to FIGS. 7A to 7H, various steps of a method for forming a semiconductor device are illustrated according to another embodiment of the present application. The method can also be used to form the semiconductor device 100 shown in FIG. 1. Different from the embodiment described with reference to FIGS. 6A-6H, an integrated conductive block is used in this embodiment and is divided to form individual conductive blocks in different semiconductor devices.

Referring to FIG. 7A, a package substrate 710 is provided. The package substrate 710 may include a plurality of predefined substrate units arranged in a strip manner. The plurality of substrate units can be isolated from each other by singulation channels 712. The singulation channels can provide cutting areas to singulate the package substrate 710 into individual semiconductor devices.

Afterwards, referring to FIG. 7B, electronic components 721 and 722 (for example, discrete devices) and at least one integrated conductive block 730 are mounted on a top surface of the package substrate 710. The integrated conductive blocks 730 is preformed, and includes an insulating substrate 734 and at least two conductive pillars 732 extending through the insulating substrate 734. The integrated conductive blocks 730 may extend across the singulation channel 712, and the at least two conductive pillars 732 may be positioned on different sides of the singulation channel 712. Thus, after the integrated conductive block 730 and the package substrate 710 are singulated, the conductive pillars 732 on different sides of the singulation channel 712 may form individual conductive blocks in different semiconductor devices.

Afterwards, referring to FIG. 7C, electronic components 723 and 724 (for example, semiconductor chips) are mounted on the top surface of the package substrate 710.

Afterwards, referring to FIG. 7D, an encapsulant 740 is formed on the top surface of the package substrate 710 to encapsulate the integrated conductive block 730 and the electronic components 721, 722, 723 and 724.

Afterwards, referring to FIG. 7E, the encapsulant 740 is grinded to expose the top surface of the conductive pillars 732 of the integrated conductive block 730 and the top surface of the electronic component 723.

Afterwards, referring to FIG. 7F, an electromagnetic interference (EMI) shield 752 is formed on the top surface of the encapsulant 740. The EMI shield 752 is electrically coupled to the conductive pillars 732 of the integrated conductive block 730 and thermally coupled to the electronic component 723.

Afterwards, referring to FIG. 7G, a saw blade 770 may be used to singulate the integrated conductive block 730 and the package substrate 710 through the singulation channels 712. For example, as shown in FIG. 7G, the integrated conductive block 730 may be singulated into individual conductive blocks 730-1, 730-2 and 730-3, which can be used in individual semiconductor devices. In some other embodiments, a laser cutting tool may be used to singulate the integrated conductive block 730 and the package substrate 710.

Afterwards, referring to FIG. 7H, a thermal interface material (TIM) layer 756 is formed on the EMI shield 752, and a heat spreader 754 is attached on the TIM layer 756. Thus, a heat dissipation cap 750 including the EMI shield 752, the TIM layer 756 and the heat spreader 754 is connected to the conductive block 730-1 to form an enclosed structure, and the electronic components 721, 722, 723 and 724 are accommodated within enclosed structure. Further, as shown in FIG. 7H, a plurality of conductive bumps 760 are formed on a bottom surface of the package substrate 710. The conductive bumps 760 may be used for electrically connecting the semiconductor device to an external device or substrate.

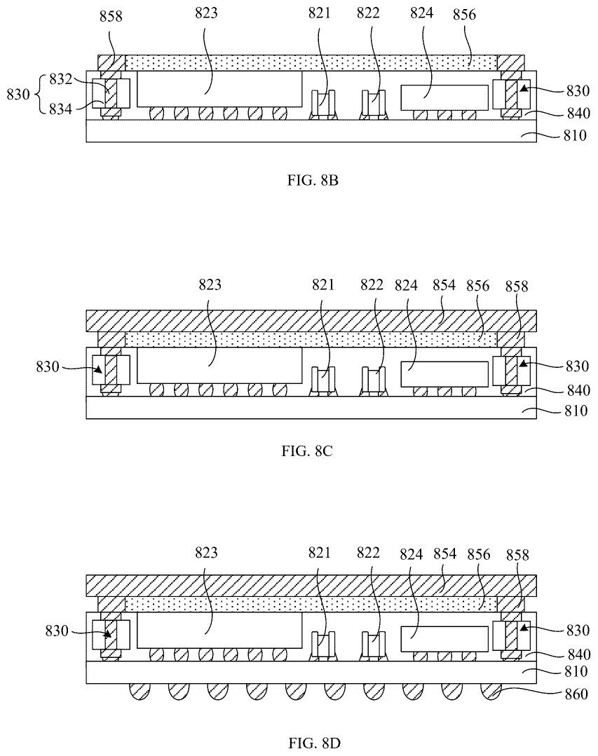

Referring to FIGS. 8A to 8D, various steps of a method for forming a semiconductor device are illustrated according to another embodiment of the present application. The method can also be used to form the semiconductor device 400 shown in FIG. 4.

Referring to FIG. 8A, a semiconductor package 801 is provided. The semiconductor package 801 may include a package substrate 810, at least one preformed conductive block 830 and a plurality of electronic components 821, 822, 823 and 824 mounted on a top surface of the package substrate 810, and an encapsulant 840 formed on the top surface of the package substrate 810. The preformed conductive block 830 may include an insulating substrate 834 and at least one conductive pillar 832 extending through the insulating substrate 834. The encapsulant 840 may expose a top surface of the conductive pillar 832 of the conductive block 830 and a top surface of the electronic component 823. For example, the package 801 may be formed by the method described with reference to the FIGS. 6A-6E, and will not be elaborated herein.

Afterwards, referring to FIG. 8B, an interconnection layer 858 is formed on the top surface of the conductive pillar 832 of the conductive block 830, and a thermal interface material (TIM) layer 856 is formed on the top surface of the electronic component 823. In some embodiments, the TIM layer 856 may include a material having a melting point near room temperature, such as Ga, InGa, InGaSn, etc. The interconnection layer 858 may enclose the liquid TIM layer 856, and prevent it from leaking to the outside. In some embodiments, the TIM layer 856 may include solder, silver, an indium/silver alloy, or other suitable materials. The TIM layer 856 may be formed by spray coating, plating, sputtering, or any other suitable metal deposition process. In some embodiments, the interconnection layer 858 may be made of a conductive material such as solder, conductive ink, conductive epoxy, or other suitable materials, and may be formed by spray coating, plating, sputtering, or any other suitable metal deposition process.

Afterwards, referring to FIG. 8C, a heat spreader 854 may be attached on the interconnection layer 858 and the TIM layer 856. In some embodiments, the interconnection layer 858 and the TIM layer 856 may be reflowed to solder the heat spreader 854 thereon. Thus, the heat spreader 854 is electrically coupled to the conductive pillar of the conductive block 830 through the interconnection layer 858 and is thermally coupled to the electronic component 823 through the TIM layer 856.

Afterwards, referring to FIG. 8D, a plurality of conductive bumps 860 are formed on a bottom surface of the package substrate 810. The conductive bumps 860 may be used for electrically connecting the semiconductor device to an external device or substrate.

While different processes for forming semiconductor devices are illustrated in conjunction with FIGS. 6A-6H, FIGS. 7A-7H and FIGS. 8A-8D, it will be appreciated by those skilled in the art that modifications and adaptations to the processes may be made without departing from the scope of the present invention. For example, when the preformed conductive block is formed between different electronic components of the semiconductor devices, the semiconductor device 200 shown in FIG. 2 and the semiconductor device 500 shown in FIG. 5 can be formed by the similar processes described with reference to FIGS. 6A-6H and the similar processes described with reference to FIGS. 8A-8D, respectively. Further, when the EMI shield is formed on lateral surfaces of the package substrate and the encapsulant, the semiconductor device 300 shown in FIG. 3 can be formed by the similar processes described with reference to FIGS. 6A-6H.

The discussion herein included numerous illustrative figures that showed various portions of a semiconductor device and a method for making the same. For illustrative clarity, such figures did not show all aspects of each example device. Any of the example devices and/or methods provided herein may share any or all characteristics with any or all other devices and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming a semiconductor device, comprising:
providing a package substrate;
mounting at least one preformed conductive block and at least one electronic component on a top surface of the package substrate, wherein the preformed conductive block comprises an insulating substrate and at least one conductive pillar extending through the insulating substrate;
forming an encapsulant on the top surface of the package substrate, wherein the encapsulant exposes a top surface of the conductive pillar of the conductive block and a top surface of the electronic component; and
forming a heat dissipation cap on the encapsulant to electrically couple the heat dissipation cap to the conductive pillar of the conductive block and to thermally couple the heat dissipation cap to the electronic component.

2. The method of claim 1, wherein forming the encapsulant on the top surface of the package substrate comprises:
forming the encapsulant on the top surface of the package substrate to encapsulate the conductive block and the electronic component; and
grinding the encapsulant to expose the top surface of the conductive pillar of the conductive block and the top surface of the electronic component.

3. The method of claim 1, wherein forming the heat dissipation cap on the encapsulant comprises:
forming an electromagnetic interference (EMI) shield on the encapsulant to electrically couple to the conductive pillar of the conductive block and to thermally couple to the electronic component; and
attaching a heat spreader on the EMI shield to thermally couple to the EMI shield.

4. The method of claim 3, further comprising:
forming a thermal interface material (TIM) layer on the EMI shield before attaching the heat spreader on the EMI shield.

5. The method of claim 3, wherein the EMI shielding covers lateral surfaces of the package substrate and the encapsulant.

6. The method of claim 1, wherein forming the heat dissipation cap on the encapsulant comprises:
forming an interconnection layer on the top surface of the conductive pillar of the conductive block;
forming a thermal interface material (TIM) layer on the top surface of the electronic component; and
attaching a heat spreader on the interconnection layer and the TIM layer, such that the heat spreader is electrically coupled to the conductive pillar through the interconnection layer and is thermally coupled to the electronic component through the TIM layer.

7. The method of claim 1, wherein the top surface of the electronic component is substantially flush with a top surface of the conductive block.

8. The method of claim 1, wherein the conductive block comprises an e-bar block.

9. The method of claim 1, wherein the conductive block comprises a molded inter-connect substrate (MIS).

10. A method for forming a semiconductor device, comprising:
providing a package substrate;
mounting at least one preformed conductive block and at least one electronic component on a top surface of the package substrate;
forming an encapsulant on the top surface of the package substrate, wherein the encapsulant exposes a top surface of the conductive block; and
forming a heat dissipation cap on the encapsulant to connect with the conductive block, such that the conductive block and the heat dissipation cap form an enclosed structure to accommodate the electronic component.

11. The method of claim 10, wherein the conductive block comprises an e-bar block.

12. The method of claim 10, wherein the conductive block comprises a molded inter-connect substrate (MIS).

13. A semiconductor device, comprising:
a package substrate;
at least one preformed conductive block and at least one electronic component mounted on a top surface of the package substrate, wherein the preformed conductive block comprises an insulating substrate and at least one conductive pillar extending through the insulating substrate;
an encapsulant formed on the top surface of the package substrate, wherein the encapsulant exposes a top surface of the conductive pillar of the conductive block and a top surface of the electronic component; and
a heat dissipation cap formed on the encapsulant, wherein the heat dissipation cap is electrically coupled to the conductive pillar of the conductive block and is thermally coupled to the electronic component.

14. The semiconductor device of claim 13, wherein the heat dissipation cap comprises:
an electromagnetic interference (EMI) shield formed on the encapsulant, wherein the EMI shield is electrically coupled to the conductive pillar of the conductive block and is thermally coupled to the electronic component; and
a heat spreader attached on the EMI shield, wherein the heat spreader is thermally coupled to the EMI shield.

15. The semiconductor device of claim 14, wherein the heat dissipation cap further comprises:
a thermal interface material (TIM) layer formed between the EMI shield and the heat spreader.

16. The semiconductor device of claim 14, wherein the EMI shielding covers lateral surfaces of the package substrate and the encapsulant.

17. The semiconductor device of claim 13, wherein the heat dissipation cap comprises:
an interconnection layer formed on the top surface of the conductive pillar of the conductive block;
a thermal interface material (TIM) layer formed on the top surface of the electronic component; and
a heat spreader attached on the interconnection layer and the TIM layer, wherein the heat spreader is electrically coupled to the conductive pillar through the interconnection layer and is thermally coupled to the electronic component through the TIM layer.

18. The semiconductor device of claim 13, wherein a top surface of the electronic component is substantially flush with a top surface of the conductive block.

19. The semiconductor device of claim 13, wherein the conductive block comprises an e-bar block.

20. The semiconductor device of claim 13, wherein the conductive block comprises a molded inter-connect substrate (MIS).
